(19) United States
(12) Patent Application Publication
(10) Pub. No.: US 2010/0098374 A1
(43) Pub. Date: Apr. 22, 2010

(54) OPTOELECTRONIC COMPONENT BASED ON PREMOLD TECHNOLOGY

(75) Inventor: Hans Ludwig Althaus, Lappersdorf (DE)

Correspondence Address: Kathy Manke;Avago Technologies Limited, 4380 Ziegler Road, Fort Collins, CO, 80525, US

(73) Assignee: AVAGO TECHNOLOGIES FIBER IP (SIGNGAPORE) PTE. LTD., Singapore (SG)

(21) Appl. No.: 12/254,340

(22) Filed: Oct. 20, 2008

(51) Int. Cl. G02B 6/12; G01N 23/04; H05K 3/30

(52) U.S. Cl. 385/14; 250/580; 29/832

(57) ABSTRACT

An optoelectronic component, arrangement and method are provided. The optoelectronic component comprises a premold casing having a mounting opening adapted for mounting an optical element, particularly a waveguide, an electromagnetic radiation source and/or detector adapted for generating and/or detecting electromagnetic radiation and being mounted in the premold casing, an electromagnetic radiation deflecting element mounted in the premold casing and adapted for deflecting electromagnetic radiation between the waveguide and the electromagnetic radiation source and/or detector, and a transparent medium filling at least a part of optical spaces within the premold casing.

### TECHNICAL FIELD OF THE INVENTION

The invention relates to optoelectronics.

### BACKGROUND OF THE INVENTION

Optoelectronics relates to electronic devices that source, detect and control light, usually considered a sub-field of photonics. In this context, light often includes invisible forms of radiation such as gamma rays, X-rays, ultraviolet and infrared, in addition to visible light. Optoelectronic devices may be electrical-to-optical or optical-to-electrical transducers, or instruments that use such devices in their operation.

DE 100 65 624 A1 discloses that in order to precisely align an optical waveguide in relation to an electro-optical component, the electro-optical component is fixed to a submount which can be arranged on any site on a carrier. A coupling element comprising a negative image of the contour of the submount is optionally provided for mounting the optical waveguide. The coupling element is positively fixed to the submount and receives the end of the optical waveguide. The intermediate region between the electro-optical component and the optical waveguide is filled with a transparent adhesive. The submount can be designed according to microstructure technology. The coupling element is not required if the optical waveguide is directly aligned in relation to the submount.

A need exists for an optoelectronic component that can be manufactured with reasonable effort.

### SUMMARY OF THE INVENTION

The invention is directed to an optoelectronic component, an optoelectronic arrangement, and a method of manufacturing an optoelectronic component.

According to an exemplary embodiment of the invention, an optoelectronic component is provided which comprises a premold casing (or package) having a mounting opening adapted for mounting an optical waveguide (e.g., an optical fiber, alternatively a lens, a window, a fiber coupler, etc.), an electromagnetic radiation device mounted in the premold casing, an electromagnetic radiation deflecting element mounted in the premold casing and adapted for deflecting electromagnetic radiation between the optical waveguide and the electromagnetic radiation device, and a transparent medium filling at least a part of empty spaces (or gaps) within the premold casing. The electromagnetic radiation device may be an electromagnetic radiation source for generating electromagnetic radiation and/or an electromagnetic radiation detector for detecting electromagnetic radiation.

According to another exemplary embodiment of the invention, an optoelectronic arrangement is provided which comprises a printed circuit board having electrically conductive traces, and an optoelectronic component having the above mentioned features and mounted on the printed circuit board in such a manner that a leadframe of the premold casing of the optoelectronic component is electrically coupled with the electrically conductive traces of the printed circuit board.

According to still another exemplary embodiment of the invention, a method of manufacturing an optoelectronic component is provided, the method comprising providing a premold casing with a mounting opening for mounting an optical waveguide, mounting an electromagnetic radiation device in the premold casing, mounting an electromagnetic radiation deflecting element in the premold casing for deflecting electromagnetic radiation between the optical waveguide and the electromagnetic radiation device, and filling empty spaces (particularly optical spaces) within the premold casing with a transparent medium. The electromagnetic radiation device may be an electromagnetic radiation source for generating electromagnetic radiation and/or an electromagnetic radiation detector for detecting electromagnetic radiation.

These and other aspects of the invention will become apparent from the following description of illustrative embodiments of the invention and the claims.

### BRIEF DESCRIPTION OF THE DRAWINGS

FIG. 1 illustrates a cross-sectional view of an optoelectronic transmitter module according to an exemplary embodiment.

FIG. 2 illustrates a plan view of the optoelectronic transmitter module of FIG. 1.

FIG. 3 illustrates an optics simulation graphics for an optoelectronic transmitter component having a reflector element according to an exemplary embodiment.

FIG. 4 illustrates an optics simulation graphics for an optoelectronic receiver module according to an exemplary embodiment having a reflector element.

FIG. 5 illustrates an optics simulation of mapping light between a fiber and a receiver chip according to an exemplary embodiment.

FIG. 6 illustrates a cross-sectional view of an optoelectronic receiver module according to an exemplary embodiment.

FIG. 7 illustrates a plan view of the optoelectronic receiver element of FIG. 6.

FIG. 8 illustrates a side view of an optoelectronic transmitter module according to an exemplary embodiment during assembling.

FIG. 9 illustrates the optoelectronic transmitter module of FIG. 8 in a later stage during assembling.

FIG. 10 illustrates a plan view of an optoelectronic transmitter component according to an exemplary embodiment.

FIG. 11 illustrates a plan view of an optoelectronic transmitter module according to an exemplary embodiment.

FIG. 12 illustrates a side view of an optoelectronic receiver module according to an exemplary embodiment without a transparent filling medium.

FIG. 13 illustrates a plan view onto a mounting plane of an optoelectronic receiver module according to an exemplary embodiment.

FIG. 14 illustrates a plan view of an optoelectronic transceiver module according to an exemplary embodiment.

FIG. 15 illustrates a detailed view of the bidirectional optoelectronic transceiver module of FIG. 14.

### DESCRIPTION OF EXEMPLARY EMBODIMENTS OF THE INVENTION

Before describing the figures in detail, some general explanations of exemplary embodiments will be given.

According to an exemplary embodiment, an optoelectronic receiver or transmitter or transceiver (that is receiver and transmitter) module may be provided having a plurality of components mounted within a premold casing.

Such a premold housing may be a molded plastic component having embedded therein a leadframe structure. A premold casing may be a hollow casing having a mounting opening through which an optical fiber or any other optical waveguide is mountable by a user. According to an exemplary embodiment, the mounting of the optical fiber may be performed at a user's side, i.e. not at a factory side. Consequently, the optoelectronic component may be installable in a flexible manner anywhere for any field of application.

According to an exemplary embodiment, the optoelectronic component may further have an electromagnetic radiation source such as an infrared, visible, optical or ultraviolet emitting active component such as a light emitting diode or a laser diode.

Additionally or alternatively, an electromagnetic radiation detector may be provided in the optoelectronic component for detecting electromagnetic radiation such as visible optical light, infrared radiation or ultraviolet radiation.

The electromagnetic radiation source/detector as well as an electromagnetic radiation deflecting element may both be mounted keyed in the premold casing. For this purpose, a further mounting opening may be formed in the premold casing via which first the electromagnetic radiation source and subsequently the electromagnetic radiation deflecting element may be assembled within the premold casing, allowing for a simple assembly procedure.

The electromagnetic radiation deflecting element may deflect the electromagnetic radiation between an optical fiber (when being installed in the mounting opening) and the electromagnetic radiation source/detector. Such an electromagnetic radiation deflecting element may be adapted as a focusing optical element efficiently transferring electromagnetic radiation between a horizontally mounted electromagnetic radiation source/detector on the one hand and a horizontally aligned optical fiber. In other words, a horizontal light beam from the optical fiber may be focused or deflected onto the electromagnetic radiation detector, or a vertical light beam from the electromagnetic radiation source may be focused or deflected into the optical fiber.

The optoelectronic component may further comprise a transparent medium which may be casted to fill gaps or volumes with air within a hollow portion of the premold casing between the components installed therein. Such an optically transparent medium will, due to its optical transparency, not disturb propagation of electromagnetic radiation between fiber and electromagnetic radiation source/detector and may at the same time ensure a constant optical relationship between the individual optoelectronic components of the optoelectronic component. Thus, the transparent medium may contribute to keep the optical properties constant between the optoelectronic constituents, the deflecting element and the fiber. This means that the optical space between them and their surfaces with optical refractive changing properties may be maintained in a defined manner, during all environmental influences during assembling to the board (SMT processes), operation and storage.

By inserting a dummy element in the mounting opening during filling an interior of the premold casing with a transparent medium (and optionally during hardening the latter), a later guiding volume for attaching the fiber may be securely prevented from being filled with the transparent medium, thereby defining a geometry of a fiber to be inserted into the premold casing at a later stage. Furthermore, the geometry of such a dummy may also define the optical properties of the system, for instance may be curved to impress an inverse curvature to the adjacent transparent material to provide a lens function or the like.

The transparent medium may be made of a flexible material so as to allow an optical fiber to adapt with physical contact (with index matching) to the transparent medium. This may improve the optical boundary properties between transparent medium and fiber, thereby allowing to use even optical fibers without perfect surface properties without the danger of losing too much light intensity by scattering and/or reflection.

When an embedded leadframe (having electrically conductive traces for electrically connecting an interior of the premold casing with an exterior thereof) is provided in the premold casing, the leadframe may be used for electrically connecting the electromagnetic radiation source and/or detector to an external periphery, for instance for power supply, signal transmission, etc. In other words, when the optoelectronic component is mounted, for instance in an SMT (Surface Mounted Technology) manner, the leadframe comprising a plurality of electrically conductive traces may allow for an external electric contacting by a reflow solder process to the electromagnetic radiation source/detector accommodated within the premold casing. By forming the premold casing by injection molding, the costs may be kept low, but also the fiber optic component may withstand the high temperatures of the reflow soldering process of SMT.

The mounting opening through which a fiber may be mounted and a further mounting opening through which the electromagnetic radiation source/detector and the electromagnetic radiation deflecting element may be mounted may both be formed in the premold casing and may be arranged basically perpendicular to one another. For instance, it is possible to mount the electromagnetic radiation source/detector by inserting it in a vertical manner onto a horizontal plane within the premold housing. Also the electromagnetic radiation deflecting element may be mounted after vertically inserting it into the premold casing. In contrast to this, the optical fiber may be plugged horizontally into the mounting opening allowing an easy operation and an arrangement of the optical fiber which is compatible with a geometry of a surface mount technology.

The electromagnetic radiation deflecting element may comprise a reflection surface, for instance a surface having a reflectivity of larger than 80%, particularly of larger than 95%. Such a reflection surface may be aspherically shaped, particularly may be free form shaped. By designing the shape of the reflection surface using a computer system, it is possible to adjust the reflection characteristics in such a manner that a beam propagating through the optical fiber is deflected to be focused onto an electromagnetic radiation detector. Here, the aspherical shape of the deflector may be adapted to the numerical aperture of the used fiber for optimum light coupling. In an opposite propagation direction, an electromagnetic radiation source may irradiate or emit electromagnetic radiation within an emission angle. Such a divergent light bundle may be deflected to form a parallel or focused beam geometrically adapted to diameter and numerical aperture of the used fiber, for optimum coupling.

The electromagnetic radiation deflection element may be at least partially mounted, keyed to sidewalls of the premold housing, whereas optionally a second portion of the electromagnetic radiation deflecting element may be mounted on a bottom within the premold casing. On this bottom, also the electromagnetic radiation generator/detector may be mounted. Such a geometry may allow for an accurate spatial alignment of the individual components to one another. Optionally, alignment markers may be used to further increase the spatial accuracy with which the individual components are mounted relative to one another.

The transparent medium may extend up to a section of the mounting opening that, upon mounting the optical fiber in the mounting opening, a front surface of the inserted optical fiber directly abuts against the transparent medium. Such a configuration may allow for a proper optical coupling between fiber and casing without the need of additional optical components.

When the transparent medium is mechanically flexible, for instance is made from a gel-like material, an abutment of an end face of the fiber to the flexible transparent medium may result in a deformation of the flexible material so that a surface topography of the flexible medium is matched to a rough surface of the fiber, thereby allowing for a proper optical coupling without scattering and reflections. By taking this measure, it may be possible to use optical fibers even when these have end surfaces which are not completely planar. Consequently, also an unskilled user may install an optical fiber within the optoelectronic component without the need of performing a complex adjustment procedure.

It is also possible to match the reflection indices of the optical fiber and the transparent medium. If these are the same or basically same (for instance deviate by less than 5%) undesired reflection losses at a boundary surface between optical fiber and transparent medium may be suppressed.

It is also possible to mount integrated circuits such as a driver IC for an electromagnetic radiation source or an amplifier IC for an electromagnetic radiation detector within the premold casing close to the electromagnetic radiation source/detector. This may keep electrical paths short, thereby suppressing the generation of artifacts in signals communicated between the individual components. The optoelectronic component according to an exemplary embodiment may be directly used to be mounted on a printed circuit board (PCB) or any other support, for instance by reflow soldering. Due to the construction and the specific material of the premold housing (package) of the optoelectronic component, it is possible that even the high temperatures during soldering, for instance 260° C. or more, do not deteriorate the performance of the optoelectronic component. Since the described architecture is compatible with the surface mounted technology, it is possible to flexibly fasten the optoelectronic component at any desired printed circuit board (PCB), thereby allowing for the production of optoelectronic systems with low cost.

By using the premold technology, it is possible to implement the components such as the transparent medium in such a manner that the properties of these components (for instance the optical transparency of the transparent medium) are not negatively influenced by a soldering procedure involving temperatures of 260° C. and more. As a material for the transparent medium, it is possible to use silicones or resins that are capable of withstanding temperatures of 300° C. without losing their transparent property.

The electromagnetic radiation deflection element may provide both a focusing and deflecting task simultaneously. By properly shaping the surface of the electromagnetic radiation deflection element, it is possible to omit lenses or other optical elements in the optical path so that the entire focusing and deflection function may be performed by the deflection surface.

The premold casing may be formed, prior to a chip assembly procedure, to provide an accommodation space for receiving various components of the optoelectronic component. A leadframe structure may be inserted into an injection molding device so that injection molding of a plastic material may embed the leadframe which is then fixedly connected within the casing and still allows for an efficient coupling between components within the premold housing and components outside of the premold housing. Thus, according to an exemplary embodiment, a premold housing for an SMT compatible fiber optic transmitter/receiver module may be provided.

An economically manufacturable optoelectronic component may be provided which may serve as a transmitter module or as a receiver module in a fiber optic signal, communication message or information transmission path. Such an optoelectronic component may be manufactured in small dimensions of, for instance, smaller than 2 mm×2 mm×4 mm. The component may be manufacturable with economic leadframe plastic housing technology for microelectronic components and may have, as optoelectronic and electrically active electronic chips, a light emitting diode or a laser chip together with a driver IC as a transmitter, optionally in combination with passive electronic components, devices or chips such as capacitors, inductors or ohmic resistors. In a configuration as a receiver, a photodiode chip and an amplifier IC may be provided, optionally in combination with passive electronic components, devices or chips such as capacitors, inductors or ohmic resistors.

A fiber access may allow for accommodating a properly dimensioned fiber such as a glass fiber or a polymer optical fiber (POF) (for instance having a diameter of up to 1 mm). Alternatively, a fiber bundle (for instance having a diameter of up to 1 mm) formed by a plurality of thin individual fibers can be accommodated within the mounting opening. This may allow for an efficient coupling of light into (or out of) the premold casing to (or from) the active chip accommodated therein. It is possible that the fiber axis extends parallel to the mounting plane (electrical contact plane) of the component. Thus, a simply pluggable and fixable fiber connection may be made possible in combination with a small height of the component (for instance less than 2 mm) so that an efficient coupling of light between active chip and a fiber is possible without the need of performing an active adjustment of individual components.

According to an exemplary embodiment, the leadframe plastic housing technology may be implemented as a so-called premold housing technology in connection with the employment of micro optic beam forming and deflection elements for receiver and/or transmitter. From the point of view of a manufacturing procedure, the reflector element to be implemented in the casing may be handled like a semiconductor chip. For filling a remaining air volume within the premold casing, it is possible to mold resin into the premold casing.

Based on a leadframe premold housing technique, active chips may be mounted highly efficiently (leadframe mounting, reel to reel). The electrooptical (or optoelectrical) functionality for fiber optics may be obtained by the addition of a micro optic element (micro reflector). It may be advantageous to use a focusing reflector element enabling a parallel supply of the fiber to the board. The simultaneous focusing of the propagating beam at the reflector element may allow to adjust a desired distance between fiber and chip (for instance LED, laser or photodiode) in order to apply standardized mounting and/or bonding technologies to thereby achieve a simple and cost-efficient chip design (front backside contacts, nail head bonding, etc.). Simultaneously, a high degree of efficiency for coupling light into the fiber and out of the fiber may be achieved.

The free space created by the reflector element may provide the opportunity to use an optically transparent medium (immersion) in order to protect and align the optical surfaces of reflector element and electrooptical chip. By the immersive filling of the optical space between chip and fiber, it is possible to avoid problems resulting from a disturbing optical boundary at the end of the fiber.

This may allow to omit a polishing procedure for improving the surface quality of the fiber, without losing too much coupling efficiency. It may be sufficient to cut polymeric fibers with simple tools (knife, scissor, etc.) and to couple such a simply processed polymeric fiber to the electrical radiation deflection element without or with a reasonable loss of intensity. Thus, it is possible that a polymer optical fiber transmission path can be installed even by an unskilled user, thereby being compatible with home network application requirements.

According to an exemplary embodiment, it is possible to adapt the optoelectronic component as a bidirectional transceiver component allowing to provide both a transmitting and receiving function. The bidirectional functionality can be achieved optically with a corresponding geometric design of the reflector element. Thus, the deflecting and focusing freeform area of the reflector element can be designed in such a manner that a transmitting chip assembled in premold leadframe technology (for instance a VCSEL chip) may couple the emitted light to at least 50% into the coupled fiber, and on the other hand, the received light from the same fiber may be focused onto a receiver chip close to the VCSEL to at least 50% or more. When also a transmission drive IC and a receiver amplifier IC are assembled with corresponding chips in a mounting technology within the module housing using leadframe technology, it is possible to realize a very efficient transceiver architecture.

The transparent medium may fill a space within the premold casing along an entire propagation path of the electromagnetic radiation between the waveguide and the electromagnetic radiation source and/or detector. Remaining gap portions within the premold casing may remain unfilled or may be filled as well. When the optical path is filled with the transparent medium, any environmental influences on the light path may be safely prevented.

It may be advantageous to implement such an embodiment when alternatively arranged transmitter/receiver or transceiver modules are installed on a circuit board of a transmission system. The design of such a module in the premold housing may allow for both a transceiver arrangement with uni- and bidirectional operated one fiber or duplex fiber arrangements.

According to an exemplary embodiment, a cost efficiently manufacturable fiber optical transmitter/receiver component may be provided particularly for applications of polymer optic fibers and glass fibers or fiber bundles having a large (for instance in a range between 200 μm and 1 mm) optical diameter, which can be connected to one another without adjustment, simply by performing a plugging procedure.

It is possible to mount an optoelectronic device according to an exemplary embodiment using SMT onto an electric system board. The fibers may be guided to an assembly plane of the board in order to save space. The electrooptical (LED, laser, pin photodiode) and/or electric (driver IC, amplifier IC) chips may be mounted in efficient leadframe premold technology. The fiber supply opening (receptacle) may be arranged in the premold housing with an efficiently manufacturable high precision (tolerances of less than 5 μm).

The optical connection between the mounted optoelectronic transmitter and/or receiver chip may be realized after a previous control of a successful assembly (position, function, etc.) by the insertion of the deflection element. The reflective optical surface may be designed in such a manner that an aspheric freeform reflecting surface allows a focusing of a light bundle emitted by the transmitter in a divergent manner onto the fiber. It is also possible that a divergent light bundle exiting the fiber is focused onto the receiver. This allows for a highly efficient coupling of light into and out of the fiber with a mechanical distance for example of larger than 500 μm between fiber and an active chip. In this context, it is possible to calculate an appropriate freeform reflection surface geometry by optics simulation programs matching with the irradiation properties of the transmitter chip and/or the fiber for the receiver chip. This may combine a high coupling tolerance with a high mounting tolerance.

The large mechanical distance between fiber and chip in combination with the efficient optical coupling into and out of the fiber may allow to use a standard wire bond procedure for the respective chip connections as well as a protecting chip cover with an optical transparent medium (for instance GlobeTop, immersion, cast resin).

The optically transparent medium (immersion) should be maintained within the premold housing. Since it is not absolutely necessary that this optical transparent medium has a high mechanical robustness, it can generate a further advantage according to an exemplary embodiment which is related to the optical immersion of the fiber end face and the chip surface. This means that when the immersion medium has essentially the same refraction index as the fiber core, a physical contact to the fiber end face may eliminate or suppress reflection losses at the fiber end surface to air. Otherwise, using a polished end face, such losses may be usually at least 4%, and using an unpolished broken or cut end surface, such losses may be larger than 50% to up to 90% with a correspondingly scattering end surface.

When the mechanical consistency of the immersion medium is designed in such a manner that it is gel-like, this may have the consequence that the fiber end face, when being inserted or plugged into the fiber, may be coated or wetted by the flexible transparent medium so that the coupling of light out of the fiber and into the fiber is not deteriorated, even under undesired circumstances in which the fiber is only cut and not polished. In such an embodiment, when assembling the optoelectronic component, it may be dispensable to use special tools or to trim the fiber end.

It is further possible to design the freeformed reflection surface in such a manner that the entire component is formed as a transceiver, that is for bidirectional optical communication. In this context, one configuration may use a single fiber for both transmission directions, another configuration may use two fibers for the two transmission channels. Even in such an embodiment, the manufacturing technology for the transmission/receiving component may be maintained. The only change may be a corresponding match of the leadframe premold housing for the mounting of transmitter and receiver chip with corresponding ICs. In such an embodiment, the housing can be configured with a single fiber supply and also with a double fiber supply. The splitting and focusing of the received light from the fiber onto the receiver chip and the focusing of the light to be emitted from the transmitter chip may be realized with one fiber or one of duplex fibers with a correspondingly designed freeform area of the reflector element. In this context, it may be advantageous to implement the reflector optics in a manner so that an efficient off-axis coupling of the fiber with geometrically next to one another mounted transmitter and receiver chips on the leadframe is obtained. By a corresponding design of the leadframes and the premold packages the optical and electric shieldings between the transmitter and receiver chips and their corresponding integrated circuit may be ensured.

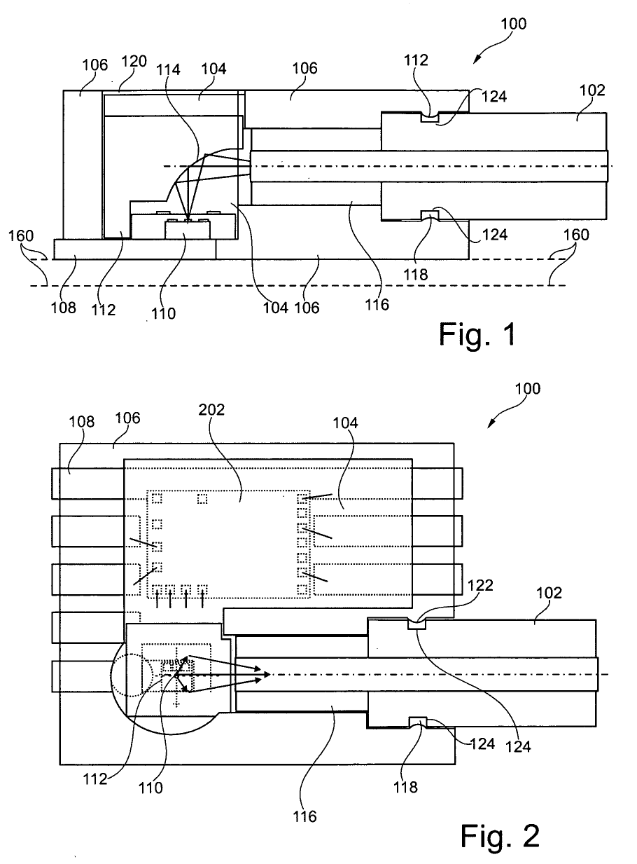

FIG. 1 illustrates the functional fiber optic components of the optoelectronic transmitter module 100 together with an optical fiber 102 and a transparent medium 104 filling empty spaces within a premold casing 106 which is integrally formed with a leadframe 108 and in which various optoelectronic components are housed.

Particularly, the optoelectronic transmitter module 100 comprises a light emitting diode 110 for generating an electromagnetic radiation beam which is directed towards a deflection and focusing element 112 having an aspherically shaped reflection surface 114. The reflection surface 114 deflects and focuses the light emitted by the light emitting diode 110 first towards an auxiliary sleeve piece 116 (as an optical coupler element) and subsequently to the optical fiber or direct to the optical fiber 102 received within a mounting opening 118 of the premold housing 106. In the embodiment of FIG. 2, the mantle is removed from a front portion of the optical fiber 102 so that only the core remains here. Then, the tubular sleeve piece 116 may be slid over the front portion of the optical fiber 102 to adopt to the present geometric conditions.

Via the leadframe 108, the light emitting diode 110 as well as a driver integrated circuit 202 (see FIG. 2) for electrically driving the light emitting diode 110 can be electrically contacted when the optoelectronic transceiver component 100 is mounted on a printed circuit board (not shown in FIG. 1 but indicated schematically as dashed lines 160) of an optoelectronic system.

The premold casing 106 comprises a plastic housing manufactured by injection molding in which the leadframe 108 is embedded. For assembling the optoelectronic transmitter device 100, the light emitting diode 110 and subsequently the deflection element 112 are inserted via a further mounting opening 120 into the premold casing 106 and are fastened at respective wall portions within the premold casing 106.

Empty spaces within the premold casing 106 (which are not occupied by the respective elements inserted into the premold casing 106) are filled with the transparent medium 104, with exception of the mounting opening 118. The optical fiber 102 may be optically plugged into the mounting opening 118 even by an unskilled user. A locking element 122 (such as two or more protrusions, a ring, or the like) within the premold casing 106 may securely fasten the optical fiber 102 within the mounting opening 118.

By locating the driver IC 202 which is also mounted within the premold casing 106 close to the light emitting diode 110, the required switching time may be short and a high data rate may be achieved when the optoelectronic system of FIG. 1 is operated as a communication system.

The embodiment of FIG. 1 and FIG. 2 is an unidirectional transmitter optoelectronic component 100 having the transmitter chip 110 (an LED, alternatively a VCSEL), and the driver IC 202.

Basis for the optoelectronic transmitter module 100 is the leadframe 108 with the corresponding contact and wire structure for constituting and electrically connecting the respective chips 110, 202. The leadframe structure 108 is integrated in the insulating material (for instance plastic, ceramic) of the premold housing 106 so that an open microelectronic housing 106 is provided already with the required traces for connection to a mounting board (not shown), to thereby enable SMT installation of the optoelectronic transmitter device 100.

In the premold housing 106, apart from the electrical traces, the optical access 118 is provided which is shaped as a cylindrical bore allowing for guiding the optical fiber 102 and positioning the latter. The premold housing 106 may be designed as a housing being open to one side with electrical connections and a fiber opening 118 as a preformed casing.

A plurality of premold housings 106 with integrated leadframes 108 may be rolled on a roll, and can be implemented into a chip mounting procedure (die and wire bond process line). The corresponding chips such as the light emitting diode 110 and the drive IC 202 can be adhered or soldered for being mounted within the premold housing 106 and can provided with bond wires for electrical contacting, if desired or required.

The proper optical functionality of the active transmitting chip 110 may be guaranteed during the manufacture by a precise mounting procedure (for instance with an accuracy of ±20 μm) in the premold housing 106 on the corresponding leadframe 108. This procedure can be performed in the context of a standard semiconductor mounting procedure with corresponding assembly apparatuses having image recognition functionality. If desired or required, markers or other features may be provided at the premold housing 106 in an appropriate way.

After die and wire bonding, the premounted transmitter component can be tested in an electrical and electrooptical way regarding the desired functionality. An external optical access can be provided through the open mounting opening 118 of the premold housing 106 with appropriate optical components (lenses, objectives, etc.) and components (lasers, detectors, etc.) which may be implemented in the production line.

According to an exemplary embodiment, after a successful test, it is possible to provide the reflector element 112 with corresponding guide and positioning features. By automatic placement machines, the reflector element 112 may be inserted into the premold housing 106 using the further mounting opening 120.

In this context, the reflector element 112 may be handled, during an automatic manufacturing procedure, like a semiconductor chip. With the insertion of the reflector element 112, an efficient deflection of the light from the transmitter chip 110 towards the fiber 102/the fiber opening 118 (or in case of a receiver element from the fiber 102 onto a receiver chip 402, see FIG. 4 and FIG. 6) may be achieved. The spatially correct precise position of the reflector element 112 between chip 110 (or 402) and the fiber 102 can be realized by mechanical guiding structures at the reflector element 112 and the premold housing 106, and the correspondingly precise positioning of the respective chip 110 (or 402) in the premold housing 106.

Subsequently, the manufacturing procedure may fill the remaining free optical space between the chips 110, 202 (or 402) and the fiber 102 (or a dummy simulating the latter) with an optically transparent medium 104 (for instance a gel, a silicone material, GlobeTop, resin, etc.) for protection, and the mounted chip 110, 202 (or 402), and their optical surfaces respectively, may be protected against environmental influences.

In an embodiment, it is possible to use a gel-like flexible and wetting immersion medium in such a manner that an unoccupied optical space is filled, the chips are protected and the fiber 102 to be inserted into the fiber opening 118 can be contacted by this immersion surface in case of a plugging procedure. By taking this measure, it is possible to eliminate an undesired fiber-air transition and to efficiently couple light from the transmitter chip 110 into the fiber 102 (or from the fiber 102 onto the receiver chip 402) without the necessity to polish a surface of the fiber end.

For an appropriate filling of the empty spaces of the housing opening up to an end surface of the fiber supply opening 118, the fiber supply opening 118 can be closed temporarily with a correspondingly shaped fiber connection closure (or dummy) which can be taken off after having solidified the immersion medium.

In case that no wetting of the fiber end surface by the transparent medium 104 is required, a correspondingly shaped surface (for instance to provide a lens function) at the removable fiber connection closure (which may be a cylindrical element) may be provided. Such a correspondingly shaped surface of the immersion medium 104 may allow to adjust optical mapping properties of the optical path between the optical fiber 102 and the active chip 102, 402 in a desired manner. As an immersion medium, it is possible to use a solid optically transparent cast resin, which is also able to withstand the reflow solder temperatures of the SMT-process of 260° C. and higher without cracks and deterioration. The surface shaped as a lens can be used in connection with the optical properties of the reflection element 112 in order to improve the coupling which may be advantageous particularly when using thin (for instance <500 μm) fibers 102, or to improve the couple tolerances.

After having formed the immersion medium, the optoelectronic transmitter element 100 may be finished and can be tested.

For instance at the user side, it is possible to plug the fiber 102 into the fiber supply opening 118 to establish an optical communication network. Appropriate engaging or locking structures 122 can be provided at the outer edge of the premold housing 106 in the fiber supply opening 118, matching to corresponding engagement or locking elements of the optical fiber 102, such as recesses 124 as shown in FIG. 1.

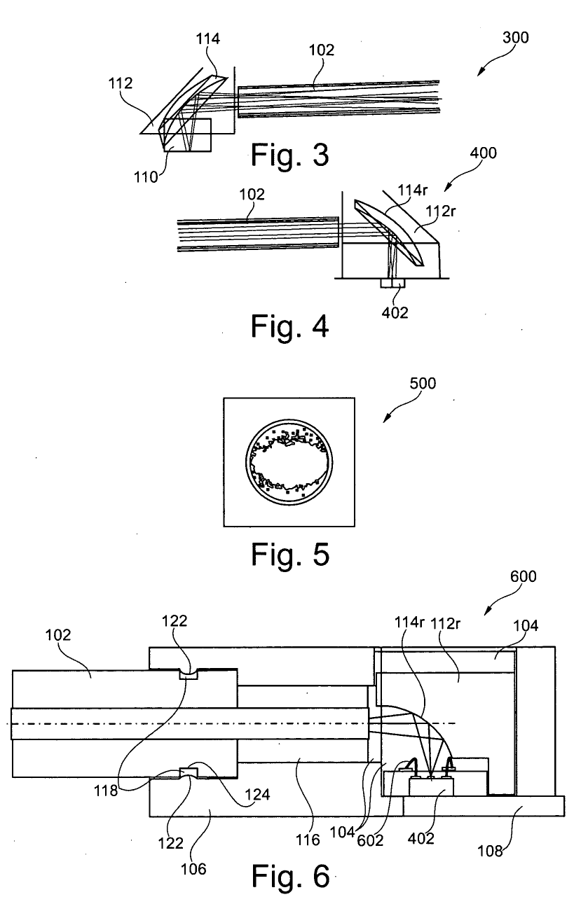

FIG. 3 shows an optics simulation graphics 300 indicative of the transmission geometry of FIG. 1 and FIG. 2. As can be taken from FIG. 3, the deflection surface 114 serves for simultaneously bending and focusing the divergent beam generated by the light emitting diode 110.

FIG. 4 shows an optics simulation graphic 400 for a receiver geometry in which an essential parallel radiation beam is supplied from an optical fiber 102 via a reflection surface 114r of a deflection element 112r towards a light detector 402 such as a photodiode. Also in this configuration, the aspherically shaped reflection surface 114r serves for bending and focusing the beam.

FIG. 5 is an optics simulation image 500 which shows the optical mapping from the fiber onto the receiver chip and further shows that the majority of the light rays are arranged well close to a center of a circle-like configuration.

FIG. 6 illustrates an optoelectronic receiver module 600 according to another exemplary embodiment. FIG. 6 illustrates a cross-sectional view of the optoelectronic receiver component 600 vertical to a mounting plane. FIG. 6 illustrates an optical fiber 102 inserted into a mount opening 118 of a premold housing 106. Bond wires 602 are shown as well. As compared to FIG. 1, the emitter 110 is substituted by the detector 402, and the deflection element 114r is adapted to the detector.

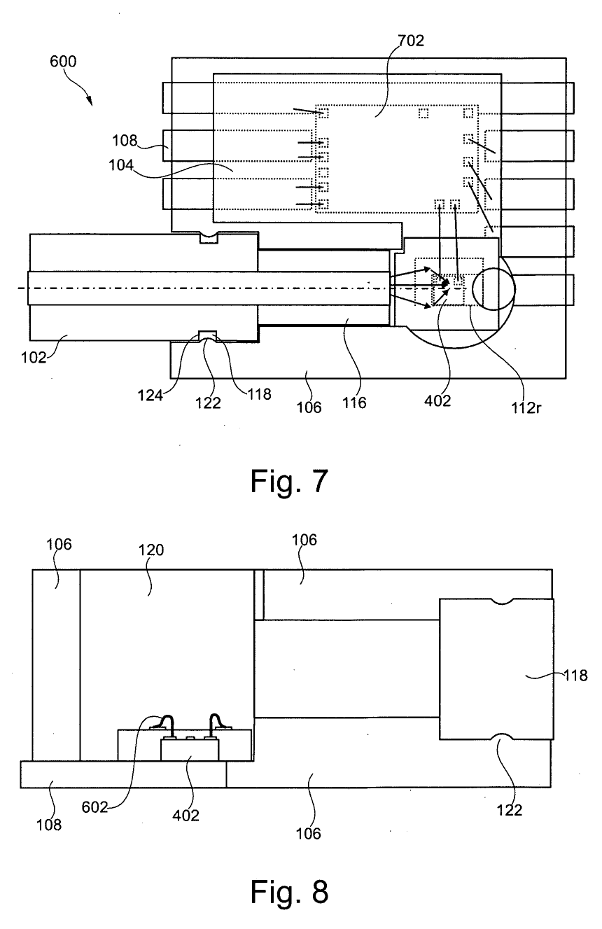

FIG. 7 shows a plan view of the optoelectronic receiver device 600 of FIG. 6 parallel to a mounting plane. FIG. 7 furthermore shows an amplifier circuit chip 702 for amplifying a signal detected by the photodiode 402.

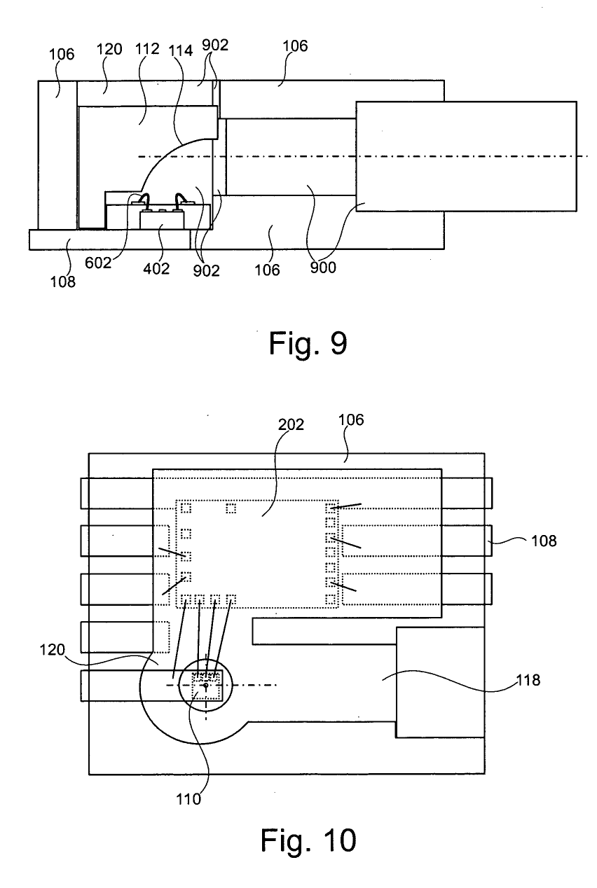

FIG. 8 and FIG. 9 show cross-sectional views during mounting the components of the optoelectronic receiver module 600 shown in FIG. 6.

FIG. 8 shows a state in which the photodiode 402 has been mounted in the premold housing 106 after insertion through the further mounting opening 120 and has been electrically contacted with the leadframe 108. Subsequently, a connection of the photodiode 402 to an amplifier chip 702 can be established, and a wire bonding 602 may be performed.

In the scenario of FIG. 9, the reflector element 112 has been inserted through the further insertion opening 120 and has been fastened at a bottom wall and at a sidewall of the premold casing 106. A dummy element 900 shaped as a combination of the optical fiber 102 and the optical coupler fiber 116 may be inserted temporarily in the mounting opening 108 before the remaining free spaces 902 within the premold housing 106 which are not yet filled with components may be filled with transparent medium 104 (not shown in FIG. 9). Subsequently, the fiber connection dummy 900 may be removed, the optional component 116 or the fiber 102 direct may be optionally inserted through the mounting opening 118. At a user side, the fiber 102 may be inserted into the mounting opening 118.

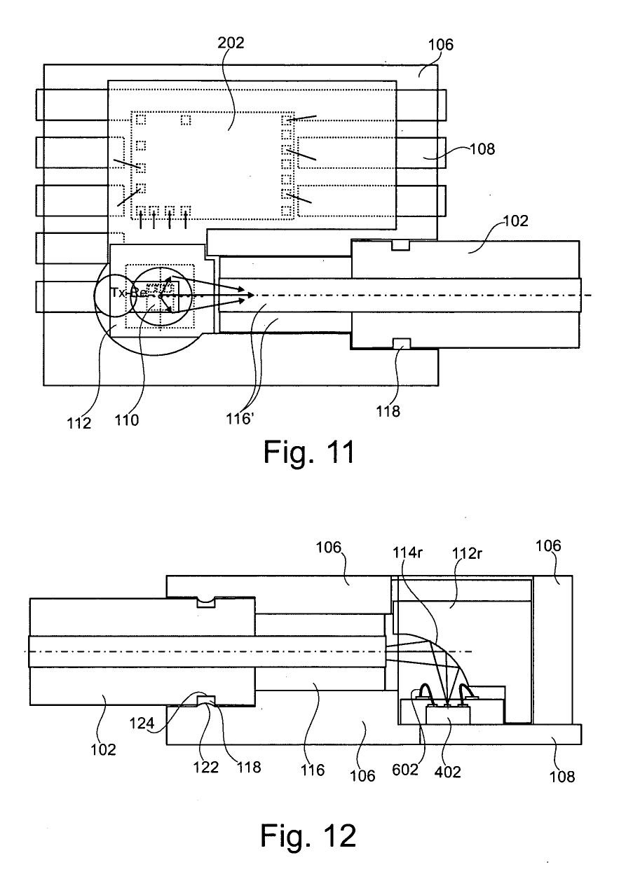

FIG. 10 and FIG. 11 illustrate the mounting of the driver chip 202 in the optoelectronic component 100.

FIG. 10 shows that the driver chip 202 as well as the light emitting diode 110 are mounted within the premold casing 106. They are mounted through the further mount opening 120 perpendicular to the paper plane of FIG. 10. In the scenario of FIG. 10, the mounting opening 118 for mounting the optical fiber 102 and the connection piece 116 is still empty.

FIG. 11 shows the scenario of FIG. 10 after having inserted an optional coupler fiber piece 116′ (which may also be denoted as a fiber stub and which may provide a focusing function) and an optical fiber 102 in the mounting opening 118, without a transparent immersion medium. Furthermore, the reflector element 112 has been mounted through the further mounting opening 120. In an alternative embodiment, the coupler fiber piece 116′ may be omitted. In such an embodiment, the optical fiber 102 (shown in FIG. 2 with a core and a cladding, compare reference numeral 116) may extend into the premold casing as far as the coupler fiber piece 116′ in FIG. 11.

FIG. 12 shows the optoelectronic receiver module 600 shown in FIG. 6 in a scenario before the immersion medium is filled in the device.

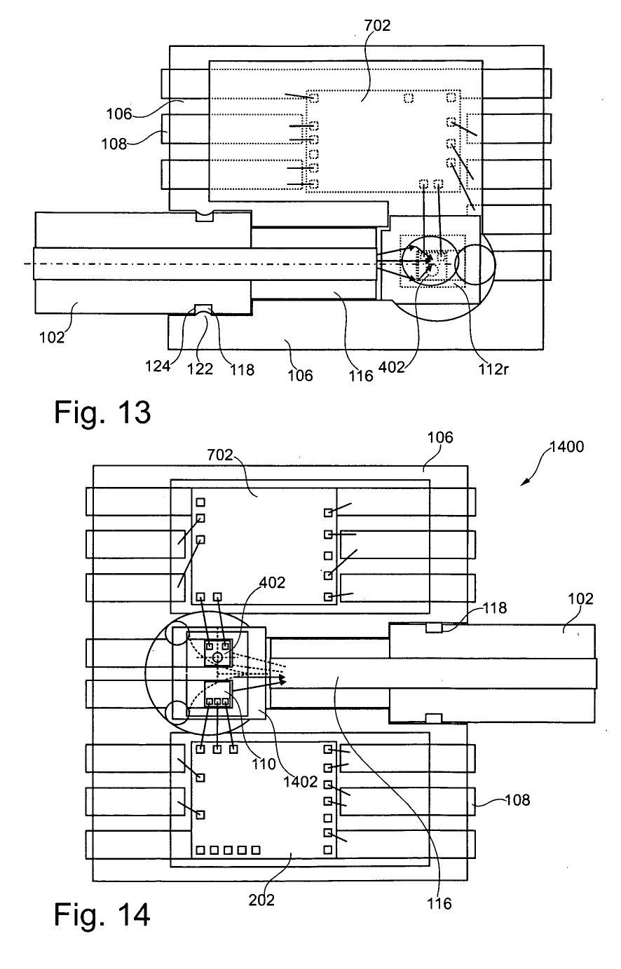

FIG. 13 shows a plan view of the optoelectronic receiver module 600 shown in FIG. 7 before filling empty spaces within the premold casing 106 with an immersion medium.

FIG. 14 shows a bidirectionally communicating optoelectronic transceiver module 1400 according to an exemplary embodiment.

As can be taken from FIG. 14, a receiver chip portion 402, 702 is integrated within the premold casing 106, and a transmitter chip portion 110, 202 is implemented in the same premold casing 106. A reflector element 1402 is provided to couple light from the LED 110 into the optical fiber 102 and from the optical fiber 102 towards the photodiode 402. Thus, the transceiver element 1400 enables both at the same time, receiving optical communication signals from the optical fiber 102 and transmitting communication signals to the optical fiber 102.

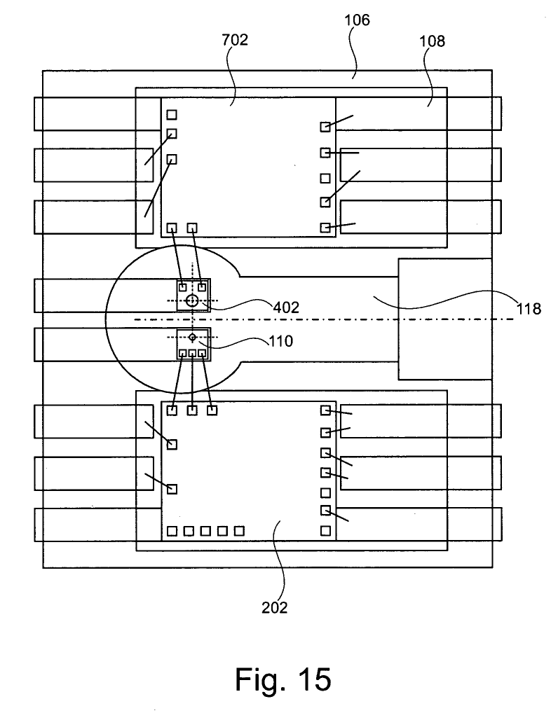

FIG. 15 shows a plan view in the mounting plane of the transceiver 1400 before inserting the optical fibers 116, 102 in the mounting opening 118.

It should be noted that the term “comprising” does not exclude other elements or features and the “a” or “an” does not exclude a plurality. Also elements described in association with different embodiments may be combined. It should also be noted that reference signs in the claims shall not be construed as limiting the scope of the claims.

1. An optoelectronic component comprising:
a premold casing having a mounting opening adapted for mounting an optical waveguide;
an electromagnetic radiation device adapted to function as at least one of an electromagnetic radiation source for generating electromagnetic radiation and an electromagnetic radiation detector for detecting electromagnetic radiation, the electromagnetic radiation device being mounted in the premold casing;
an electromagnetic radiation deflecting element mounted in the premold casing, wherein the electromagnetic radiation deflecting element is adapted for deflecting electromagnetic radiation between the optical element and the electromagnetic radiation device;
a transparent medium filling at least a part of gaps within the premold casing.

2. The optoelectronic component according to claim 1, wherein the premold casing comprises an embedded leadframe adapted for electrically connecting an electronic member, particularly the electromagnetic radiation device.

3. The optoelectronic component according to claim 2, wherein the electromagnetic radiation device is mounted in the premold casing to be electrically coupled to the embedded leadframe.

4. The optoelectronic component according to claim 1, wherein the premold casing is formed by injection moulding.

5. The optoelectronic component according to claim 1, wherein the premold casing comprises a further mounting opening defining a geometrical structure adapted for mounting the electromagnetic radiation device and the electromagnetic radiation deflecting element in the premold casing.

6. The optoelectronic component according to claim 5, wherein the mounting opening and the further mounting opening are formed in the premold casing in such a manner that a mounting direction along which the optical waveguide is to be inserted in the mounting opening is perpendicular to a further mounting direction along which the electromagnetic radiation device and subsequently the electromagnetic radiation deflecting element are to be inserted in the premold casing.

7. The optoelectronic component according to claim 1, wherein the electromagnetic radiation device is an electromagnetic radiation source selected from a group consisting of a light emitting diode and a vertical cavity surface emitting laser adapted for generating an electromagnetic radiation beam to be coupled into the optical waveguide via the electromagnetic radiation deflecting element.

8. The optoelectronic component according to claim 1, wherein the electromagnetic radiation device is a photodiode adapted for detecting an electromagnetic radiation beam received from the optical waveguide via the electromagnetic radiation deflecting element.

9. The optoelectronic component according to claim 1, wherein the electromagnetic radiation device comprises an electromagnetic radiation source adapted for generating an electromagnetic radiation beam to be coupled into the optical waveguide and comprises an electromagnetic radiation detector adapted for detecting an electromagnetic radiation beam received from the optical waveguide or from a further optical element via the electromagnetic radiation deflecting element.

10. The optoelectronic component according to claim 1, wherein the electromagnetic radiation deflecting element is arranged and adapted in such a manner that an average deflection angle by which the electromagnetic radiation is deflected between the optical waveguide and the electromagnetic radiation device is 90°.

11. The optoelectronic component according to claim 1, wherein the electromagnetic radiation deflecting element comprises a reflection surface.

12. The optoelectronic component according to claim 11, wherein the electromagnetic radiation reflection surface is aspherically shaped.

13. The optoelectronic component according to claim 1, wherein the electromagnetic radiation deflecting element is mounted in a structure on an inner surface portion of the premold casing which is perpendicular to a further inner surface portion of the premold casing on which the electromagnetic radiation device is mounted.

14. The optoelectronic component according to claim 1, wherein the transparent medium is arranged for filling all optical spaces between the elements forming the optoelectronic component within the premold casing with exception of the mounting opening for mounting the optical element.

15. The optoelectronic component according to claim 1, wherein the transparent medium is arranged so that an end of the optical waveguide mounted in the mounting opening directly abuts against an end face of the transparent medium.

16. The optoelectronic component according to claim 1, wherein the transparent medium is mechanically flexible so that the transparent medium aligns itself and forms a physical contact to an end surface of the optical waveguide mounted in the mounting opening.

17. The optoelectronic component according to claim 1, wherein the transparent medium has a gel consistency.

18. The optoelectronic component according to claim 1, wherein an end face of the transparent medium adjacent the mounting opening for mounting the optical waveguide is curved to form a lens.

19. The optoelectronic component according to claim 1, wherein the transparent medium has the same or at least nearly the same refraction index as an electromagnetic radiation propagating portion of the optical waveguide.

20. The optoelectronic component according to claim 1, comprising an optical coupler fiber arranged between the mounting opening and the electromagnetic radiation deflecting element to couple electromagnetic radiation between the optical waveguide and the electromagnetic radiation deflecting element.

21. The optoelectronic component according to claim 1, wherein the mounting opening is adapted to enable an insertion of the optical waveguide by plugging the optical waveguide into the mounting opening without performing an adjustment operation.

22. The optoelectronic component according to claim 1, wherein an alignment direction along which the optical waveguide is aligned when being mounted in the mounting opening is parallel to a mounting plane on which the electromagnetic radiation device is mounted in the premold casing.

23. The optoelectronic component according to claim 1, comprising an integrated circuit chip selected from a group consisting of a driver integrated circuit and an amplifier integrated circuit mounted in the premold casing adjacent to and electrically coupled with the electromagnetic radiation device.

24. The optoelectronic component according to claim 1, further comprising at least one passive electronic component selected from a group consisting of a capacitor, an inductor and an ohmic resistor.

25. The optoelectronic component according to claim 1, wherein the optoelectronic component is a surface mountable device adapted to be mountable on a printed circuit board by soldering.

26. The optoelectronic component according to claim 1, wherein the transparent medium fills a space within the premold casing along an entire propagation path of the electromagnetic radiation between the optical waveguide and the electromagnetic radiation device.

27. An optoelectronic arrangement comprising:
a printed circuit board having electrically conductive traces; and
an optoelectronic component mounted on the printed circuit board, the optoelectronic component comprising:
a premold casing having a mounting opening adapted for mounting an optical waveguide, the premold casing comprising a leadframe, and wherein the optoelectronic component is mounted on the printed circuit board in such a manner that the leadframe is electrically coupled with the electrically conductive traces of the printed circuit board;
an electromagnetic radiation device adapted to function as at least one of an electromagnetic radiation source for generating electromagnetic radiation and an electromagnetic radiation detector for detecting electromagnetic radiation, the electromagnetic radiation device being mounted in the premold casing;
an electromagnetic radiation deflecting element mounted in the premold casing, wherein the electromagnetic radiation deflecting element is adapted for deflecting electromagnetic radiation between the optical waveguide and the electromagnetic radiation device; and
a transparent medium filling at least a part of gaps within the premold casing.

28. A method of manufacturing an optoelectronic component, the method comprising
providing a premold casing with a mounting opening for mounting an optical waveguide;
mounting an electromagnetic radiation device in the premold casing, the electromagnetic radiation device being adapted to function as at least one of an electromagnetic radiation source for generating electromagnetic radiation and an electromagnetic radiation detector for detecting electromagnetic radiation;
mounting an electromagnetic radiation deflecting element in the premold casing for deflecting electromagnetic radiation between the optical waveguide and the electromagnetic radiation device;
filling at least a part of gaps within the premold casing with a transparent medium.

29. The method according to claim 28, comprising
inserting a dummy element into the mounting opening during filling the empty spaces with the transparent medium; and
removing the dummy element form the mounting opening to enable subsequent insertion of the optical waveguide into the mounting opening.
